(19) United States
(12) Patent Application Publication
(10) Pub. No.: US 2026/0362636 A1
(43) Pub. Date: Nov. 12, 2026

(54) COLD PLATE DEVICE

(71) Applicant: Delta Electronics, Inc., Taoyuan City (TW)

(72) Inventors: Chi-Min Cheng, Taoyuan City (TW); Yu-Hsuan Sha, Taoyuan City (TW); Po-Chen Wu, Taoyuan City (TW); Shu-Hong Chu, Taoyuan City (TW)

(21) Appl. No.: 19/294,087

(22) Filed: Aug. 7, 2025

(30) Foreign Application Priority Data
May 9, 2025 (CN) 202510593457.6

(51) Int. Cl. H05K 7/20

(52) U.S. Cl. CPC H05K 7/20254

(57) ABSTRACT

A cold plate device is disclosed and includes a main body, an inlet, a protrusion, and an outlet. The main body includes a first heat dissipation fin disposed within a first liquid cooling chamber and thermally coupled to a first heat-generating element via a first heat dissipation surface. The inlet is in fluid communication with the first liquid cooling chamber. A coolant enters the first liquid cooling chamber and flows horizontally through the first heat dissipation fin. The protrusion is extended downward from the main body and includes a second heat dissipation fin disposed within a second liquid cooling chamber and thermally coupled to a second heat-generating element via the second heat dissipation surface. The first liquid cooling chamber is in fluid communication with the second liquid cooling chamber via an impingement flow channel. The coolant is guided vertically toward the second heat dissipation fin and discharged through the outlet.

### CROSS-REFERENCE TO RELATED APPLICATION

This application claims priority to China Patent Application No. 202510593457.6, filed on May 9, 2025. The entireties of the above-mentioned patent application are incorporated herein by reference for all purposes.

### FIELD OF THE INVENTION

The present disclosure relates to a cold plate structure, and more particularly to a cold plate device, which provides modular heat dissipation fins and heat dissipation surfaces at different positions and heights for multiple heat-generating elements with different temperature resistance and heat dissipation requirements in a single package component, thereby realizing the application of omnidirectional heat management.

### BACKGROUND OF THE INVENTION

As the demand for generative AI accelerates the rapid growth of data centers, the bandwidth of switch chips is also growing rapidly, and co-packaged optics (CPO) technology is becoming increasingly important. The so-called CPO technology is to install the electronic integrated circuit (EIC) and the photonic integrated circuit (PIC) on the same carrier board to form a common package of module and chip, thereby replacing the optical transceiver module. In that, the optical engine is closer to the CPU/GPU, the electrical transmission path is shortened, and the transmission loss and the signal delay are eliminated. Although the CPO technology brings about a rapid increase in network transmission speed, it also faces the problem of heat dissipation. Compared with switch chips made of silicon, the temperature resistance of optical components is much lower. When the optical engine and CPU/GPU chip are close to each other, the high-temperature chip will also heat the optical components. Moreover, the two kinds of heat-generating elements are not on the same plane, which makes heat dissipation more difficult.

Since CPO is a newly developed technology, a corresponding cold plate for its application has not been developed in the industry. In the existing technology, the conventional liquid cooling plate can only dissipate the heat from the heat source on the same plane, and it is difficult to apply the conventional cold plate to the special geometric heat source such as CPO component. The difficulty lies in the fact that there are multiple heat sources and not every heat source is located at the same height, so the conventional single-plane cold plate cannot meet the application requirements of CPO component. Furthermore, if different liquid cooling plates are used for the central heat source and the surrounding optical element heat source, a lot of coolant pipes need to be connected in series. Although the heat dissipation effect is achieved, its cost and overall cold plate volume are difficult to be adopted by the market.

Therefore, there is a need of providing a cold plate device, which provides modular heat dissipation fins and heat dissipation surfaces at different positions and heights for multiple heat-generating elements with different temperature resistance and heat dissipation requirements in a single package component, thereby achieving multi-dimensional heat dissipation and ensuring cooling efficiency and uniformity of omnidirectional heat management to address the deficiencies of conventional technologies.

### SUMMARY OF THE INVENTION

An object of the present disclosure is to provide a cold plate device, which provides modular heat dissipation fins and heat dissipation surfaces at different positions and heights for multiple heat-generating elements with different temperature resistance and heat dissipation requirements in a single package component, thereby achieving multi-dimensional heat dissipation and ensuring cooling efficiency and uniformity of omnidirectional heat management.

Another object of the present disclosure is to provide a cold plate device with omnidirectional heat management, so that the heat sources of multiple different heat-generating elements are cooled at the same time, and the heat sources of different heat-generating elements are not located on the same plane. Although different heat-generating elements packaged in a single component have different temperature resistance and heat dissipation requirements, the cold plate device of the present disclosure utilizes a specific flow channel design to connect the liquid cooling chambers in different layers, so as to achieve the optimal cooling efficiency for omnidirectional heat management, and prevent the heat dissipation path from affecting the operating performance of electronic components at the same time. Taking one single co-packaged optics (CPO) component as an example, the main structure of a CPO component includes a central switch chip, and four pairs of optical elements (optical engines) arranged on the four sides of the switch chip. There are a lot of heat-generating elements. The cold plate device with omnidirectional heat management in the present disclosure forms a central vertical impingement flow channel and a peripheral horizontal flow channel through the design of liquid cooling chambers in different layers of the protrusion and the main body. The central switch chip and the eight surrounding optical elements are cooled effectively. Moreover, it prevents the central high-wattage chip from heating the optical elements located at multiple small-area heat sources around the central high-wattage chip and affecting their performance. In other words, different from the conventional liquid cooling plates that handle single-plane heat sources merely, the cold plate device of the present disclosure with omnidirectional heat management is equipped with a multi-level and multi-height adjustable heat dissipation structure to meet multi-dimensional heat dissipation needs. The heat sources at different positions and heights are cooled accurately and individually to maintain the cooling efficiency and uniformity. The heat dissipation fins and the heat dissipation surfaces thermally coupled to each heat-generating element are allowed to be detachably arranged at the bottoms of the main body and the protrusion, so that a modular design is achieved. The components can be adjusted and expanded according to the practical requirements to achieve equipment upgrades and changes. For example, the multiple heat dissipation fins and multiple heat dissipation surfaces of the main body can also be designed in layers with different heights to correspond to thermal coupling to optical elements of different specifications and sizes. Thereby, diversified configurations are achieved and the flexibility and adaptability of the entire heat dissipation system are improved. Certainly, the present disclosure is not limited thereto.

In accordance with an aspect of the present disclosure, a cold plate device is provided and includes a main body, an inlet, a protrusion and an outlet. The main body includes at least one first liquid cooling chamber, at least one first heat dissipation fin and at least one first heat dissipation surface, wherein the at least one first heat dissipation fin is disposed within the first liquid cooling chamber, and the at least one first heat dissipation fin is thermally coupled to a first heat-generating element via the at least one first heat dissipation surface. The inlet is disposed above the main body and in fluid communication with the at least one first liquid cooling chamber, wherein a coolant enters the at least one first liquid cooling chamber through the inlet, and the coolant flows through the at least one first heat dissipation fin along a horizontal direction. The protrusion is protruded downward from the main body and includes a second liquid cooling chamber, a second heat dissipation fin and a second heat dissipation surface, wherein the at least one first liquid cooling chamber is in fluid communication with the second liquid cooling chamber via an impingement flow channel, the second heat dissipation fin is disposed within the second liquid cooling chamber, and the second heat dissipation fin is thermally coupled to a second heat-generating element via the second heat dissipation surface, wherein the coolant flows through the impingement flow channel along a vertical direction and is guided to the second heat dissipation fin. The outlet is disposed above the main body and in fluid communication with the second liquid cooling chamber, wherein the coolant flows through the second heat dissipation fin, and then is discharged through the outlet.

In an embodiment, the at least one first liquid cooling chamber and the second liquid cooling chamber are misaligned in view of the horizontal direction and in view of the vertical direction.

In an embodiment, the at least one first heat dissipation surface and the second heat dissipation surface have a height difference in the vertical direction, and the second heat dissipation surface is lower than the at least one first heat dissipation surface.

In an embodiment, the at least one first heat dissipation surface includes a plurality of first heat dissipation surfaces arranged around the second heat dissipation surface in view of the vertical direction, and the second heat dissipation surface is lower than the plurality of first heat dissipation surfaces.

In an embodiment, the impingement flow channel comprises a converging nozzle, a cross-sectional area of the converging nozzle is gradually decreased along the vertical direction, so that the coolant flowing through the converging nozzle forms an impingement flow and is guided to the second heat dissipation fin.

In an embodiment, the cold plate device further includes an inlet tube, an outlet tube and a top cover, wherein the inlet and the outlet are arranged on the top cover and in fluid communication with an exterior through the inlet tube and the outlet tube, respectively, and the top cover is mounted on the main body from top to bottom to define a recirculation chamber in fluid communication with the outlet and the second liquid cooling chamber.

In an embodiment, the cold plate device further includes at least one return flow channel embedded in the protrusion and the main body, and extended from the recirculation chamber to the second liquid cooling chamber along the vertical direction, wherein the coolant in the second liquid cooling chamber is transported to the recirculation chamber through the at least one return flow channel and then discharged through the outlet.

In an embodiment, the at least one return flow channel and the impingement flow channel are misaligned in view of the vertical direction, and included in a projection range of the second liquid cooling chamber.

In an embodiment, the impingement flow channel is spatially corresponding to a center of the second heat dissipation fin, and the at least one return flow channel includes four return flow channels spatially corresponding to four corners of the second heat dissipation fin.

In an embodiment, the main body further includes a connection channel, wherein the connection channel is in fluid communication to the at least one first liquid cooling chamber and a converging nozzle of the impingement flow channel, and the connection channel and the at least one return flow channel are misaligned in view of the vertical direction.

In an embodiment, the main body further includes a plurality of spoiler columns, which are spaced apart from each other, disposed in the connection channel, and configured to evenly distribute the coolant passing through the connection channel.

In an embodiment, the at least one first heat dissipation fin and the at least one first heat dissipation surface are detachably arranged at a bottom of the main body, wherein the second heat dissipation fin and the second heat dissipation surface are detachably arranged at a bottom of the protrusion.

In an embodiment, the at least one first liquid cooling chamber includes a first upper liquid cooling chamber and a first lower liquid cooling chamber, the at least one first heat dissipation fin includes a first upper heat dissipation fin and a first lower heat dissipation fin, and the at least one first heat dissipation surface includes a first upper heat dissipation surface and a first lower heat dissipation surface, wherein the first upper heat dissipation fin is disposed within the first upper liquid cooling chamber and thermally coupled with the first upper heat dissipation surface, and the first lower heat dissipation fin is disposed within the first lower liquid cooling chamber and thermally coupled with the first lower heat dissipation surface, wherein the first upper heat dissipation surface and the first lower heat dissipation surface have different height differences relative to the second heat dissipation surface in the vertical direction.

In an embodiment, the protrusion protrudes downward from a center of a bottom of the main body, the second heat dissipation surface is square or rectangular and located on a bottom of the protrusion, and the at least one first heat dissipation surface includes eight first heat dissipation surfaces, which are arranged in pairs on four sides of the protrusion.

In an embodiment, a temperature resistance of the first heat-generating element is lower than a temperature resistance of the second heat-generating element, and a heat dissipation requirement of the second heat-generating element is greater than a heat dissipation requirement of the first heat-generating element, wherein the first heat-generating element is an optical element, and the second heat-generating element is a chip.

In an embodiment, the first heat-generating element and the second heat-generating element are packaged in a single co-packaged optics (CPO) component, the first heat-generating element comprises a photonic integrated circuit (PIC), and the second heat-generating element comprises an electronic integrated circuit (EIC).

In an embodiment, the cold plate device further includes at least one fastened portion connected to a corner of the main body, and configured to fasten the cold plate device, so that the at least one first heat dissipation surface is attached to the first heat-generating element and the second heat dissipation surface is attached to the second heat-generating element.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a schematic structural view illustrating a cold plate device according to a first embodiment of the present disclosure, taken from a top perspective;

FIG. 2 is a schematic structural view illustrating the cold plate device according to the first embodiment of the present disclosure, taken from a bottom perspective;

FIG. 3 is an exploded structural view illustrating the cold plate device according to the first embodiment of the present disclosure, taken from a top perspective;

FIG. 4 is an exploded structural view illustrating the cold plate device according to the first embodiment of the present disclosure, taken from a bottom perspective;

FIG. 5 is a schematic view illustrating the cold plate device combined with heat-generating elements according to the first embodiment of the present disclosure;

FIG. 6 is a cross-sectional structural view illustrating the cold plate device without the top cover according to the first embodiment of the present disclosure;

FIG. 7 is a schematic view illustrating the flow direction of the coolant in the first liquid cooling chamber of the cold plate device according to the first embodiment of the present disclosure;

FIG. 8 is a schematic view illustrating the flow direction of the coolant in the second liquid cooling chamber of the cold plate device according to the first embodiment of the present disclosure;

FIG. 9 is a schematic view illustrating the flow field of the coolant in the recirculation chamber of the cold plate device according to the first embodiment of the present disclosure;

FIG. 10 is a schematic view illustrating a flow direction of a coolant in a first liquid cooling chamber of a cold plate device according to a second embodiment of the present disclosure;

FIG. 11 is a schematic view illustrating a cold plate device combined with heat-generating elements according to a third embodiment of the present disclosure;

FIG. 12 is a schematic structural view illustrating a cold plate device according to a fourth embodiment of the present disclosure, taken from a top perspective;

FIG. 13 is a schematic structural view illustrating the cold plate device according to the fourth embodiment of the present disclosure, taken from a bottom perspective; and

FIG. 14 is a schematic view illustrating the flow direction of the coolant in the first liquid cooling chamber of the cold plate device according to the fourth embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “upper,” “lower,” “top,” “bottom,” “inner,” “outer,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items.

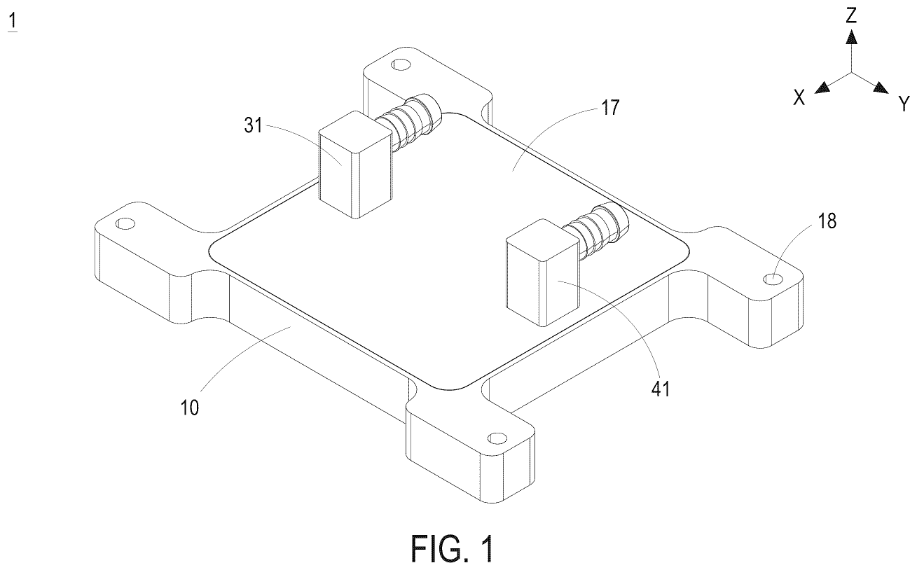

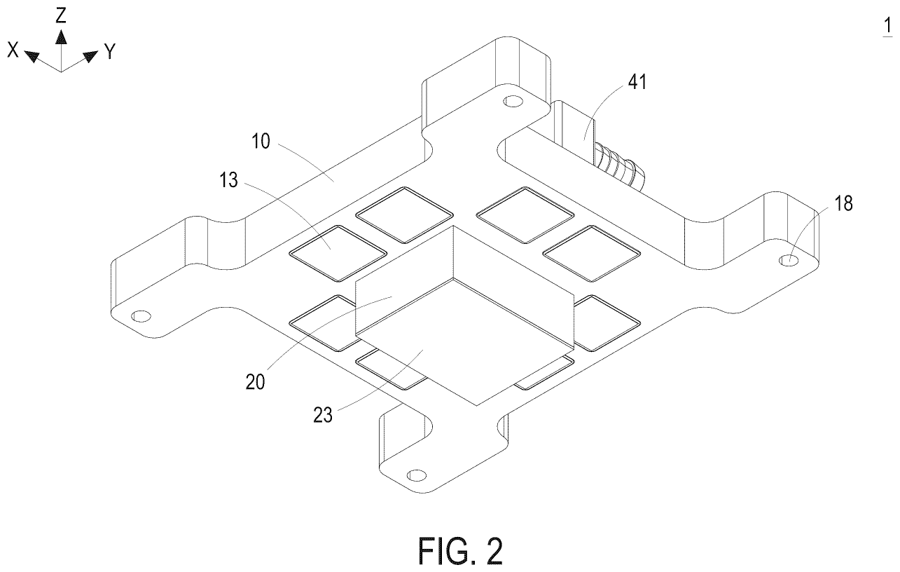

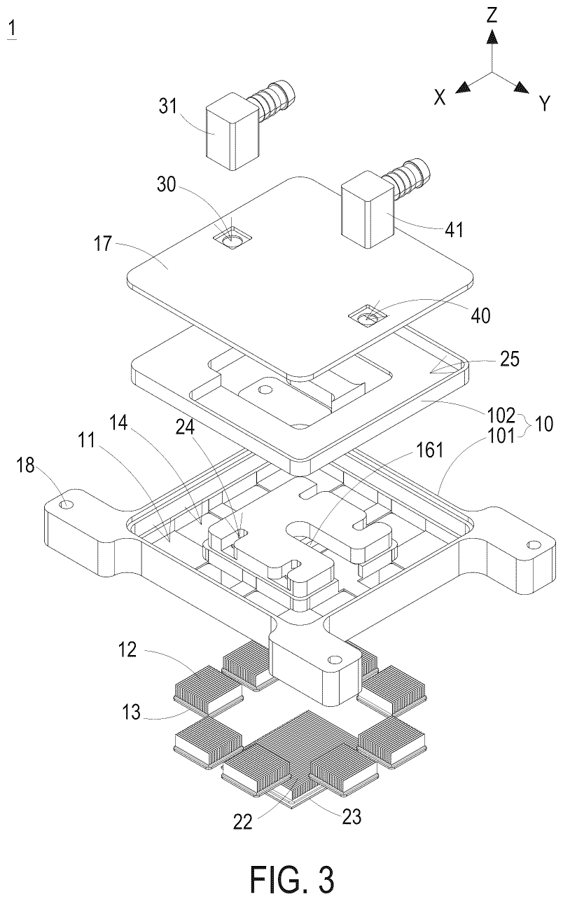

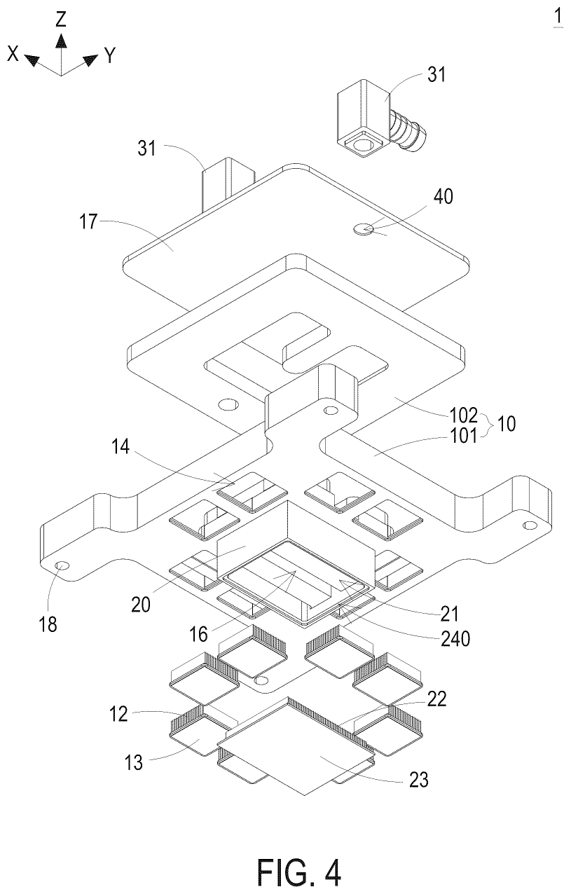

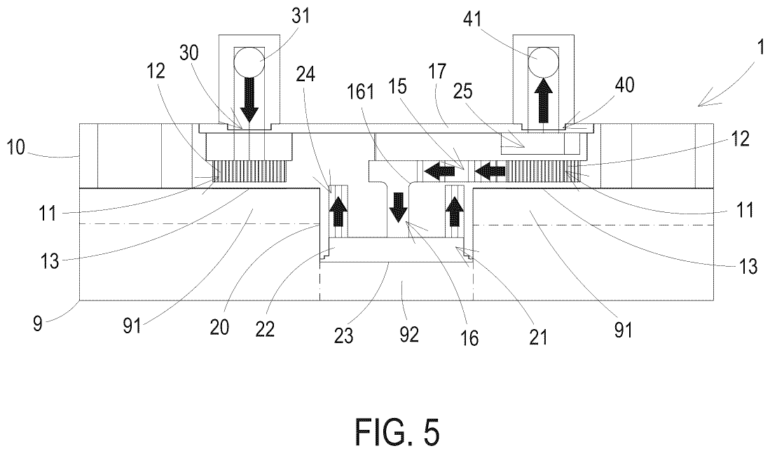

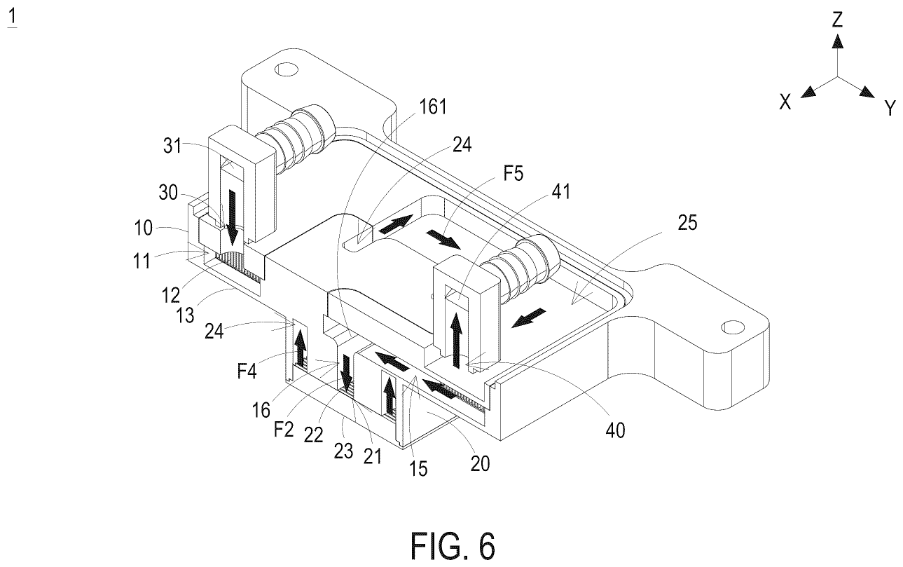

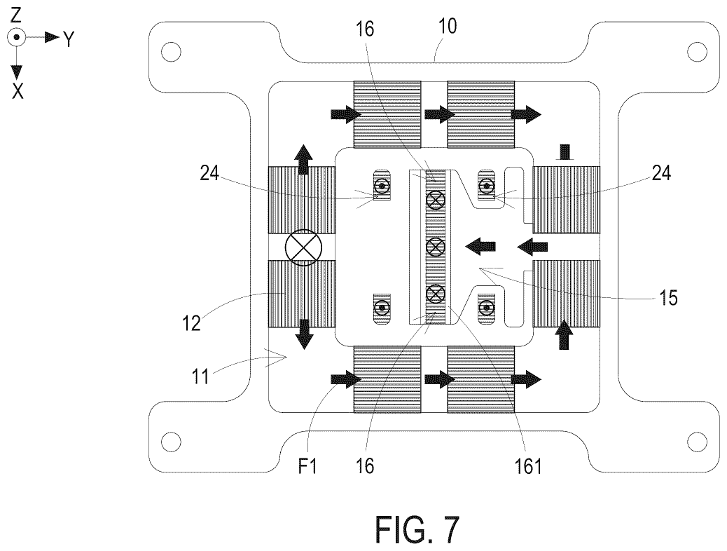

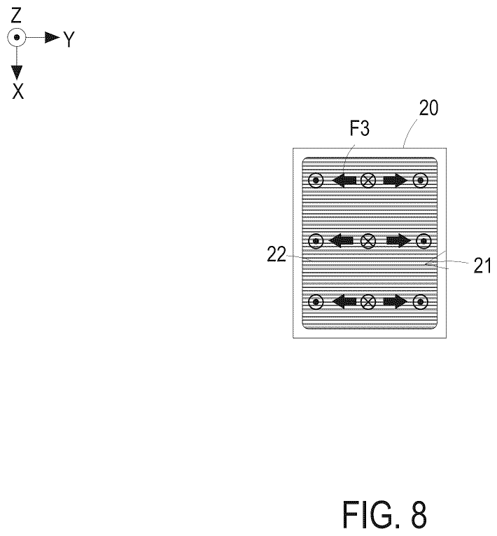

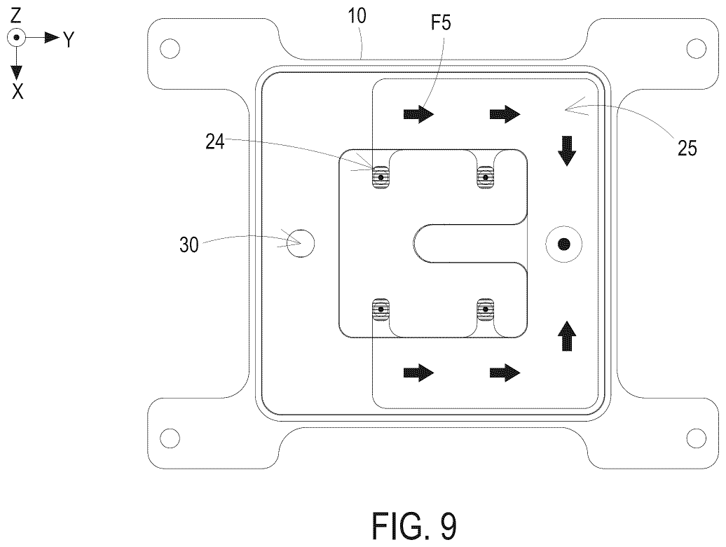

FIG. 1 and FIG. 2 are schematic structural views illustrating a cold plate device according to a first embodiment of the present disclosure. FIG. 3 and FIG. 4 are exploded structural views illustrating the cold plate device according to the first embodiment of the present disclosure. FIG. 5 is a schematic view illustrating the cold plate device combined with heat-generating elements according to the first embodiment of the present disclosure. FIG. 6 is a cross-sectional structural view illustrating the cold plate device without the top cover according to the first embodiment of the present disclosure. FIG. 7 is a schematic view illustrating the flow direction of the coolant in the first liquid cooling chamber of the cold plate device according to the first embodiment of the present disclosure. FIG. 8 is a schematic view illustrating the flow direction of the coolant in the second liquid cooling chamber of the cold plate device according to the first embodiment of the present disclosure. FIG. 9 is a schematic view illustrating the flow field of the coolant in the recirculation chamber of the cold plate device according to the first embodiment of the present disclosure. The present disclosure provides a cold plate device 1 with omnidirectional heat management, which provides modular heat dissipation fins and heat dissipation surfaces at different positions and heights for multiple heat-generating elements with different temperature resistance and heat dissipation requirements in a single package component 9, thereby achieving multi-dimensional heat dissipation and ensuring cooling efficiency and uniformity of omnidirectional heat management. In the embodiment, the cold plate device 1 includes a main body 10, an inlet 30, a protrusion 20 and an outlet 40. Preferably but not exclusively, the main body 10 is composed of an outer part 101 and an inner part 102 engaged with each other, and includes at least one first liquid cooling chamber 11, at least one first heat dissipation fin 12 and at least one first heat dissipation surface 13. The at least one first heat dissipation fin 12 is disposed within the first liquid cooling chamber 11, and the at least one first heat dissipation fin 12 is thermally coupled to a first heat-generating element 91 via the at least one first heat dissipation surface 13. The inlet 30 is disposed above the main body 10 and in fluid communication with the at least one first liquid cooling chamber 11 below. In the embodiment, a coolant (not shown) enters the at least one first liquid cooling chamber 11 through the inlet 30, and the coolant flows through the at least one first heat dissipation fin 12 along a horizontal direction, such as on the XY plane. The protrusion 20 is protruded downward from the main body 10 and includes a second liquid cooling chamber 21, a second heat dissipation fin 22 and a second heat dissipation surface 23. The at least one first liquid cooling chamber 11 is in fluid communication with the second liquid cooling chamber 21 via an impingement flow channel 16. The second heat dissipation fin 22 is disposed within the second liquid cooling chamber 21, and the second heat dissipation fin 22 is thermally coupled to a second heat-generating element 62 via the second heat dissipation surface 23. In the embodiment, the coolant flows through the impingement flow channel 16 along a vertical direction (i.e., the reverse Z axial direction) and is guided to the second heat dissipation fin 22. The outlet 40 is disposed above the main body 10 and in fluid communication with the second liquid cooling chamber 21. In the embodiment, the coolant flows through the second heat dissipation fin 22, and then is discharged through the outlet 40.

Notably, in the embodiment, the cold plate device 1 is applicable to multiple heat-generating elements with different temperature resistance and heat dissipation requirements in a single package component 9, such as a single co-packaged optics (CPO) component. Preferably but not exclusively, the main structure of CPO component includes a central switch chip and four pairs of optical elements (e.g., eight light engines) arranged on the four sides of the switch chip. That is, there are nine heat-generating elements. If the heat-generating elements are distinguished by the temperature resistance and heat dissipation requirements thereof, the nine heat-generating elements in the single package component 9 are divided into eight first heat-generating elements 91 and one second heat-generating element 92. Preferably but not exclusively, the first heat-generating element 91 and the second heat-generating element 92 respectively represent a photonic integrated circuit (PIC) and an electronic integrated circuit (EIC) packaged in the single CPO component. That is, the first heat-generating element 91 is an optical element, and the second heat-generating element 92 is a chip. Preferably but not exclusively, a temperature resistance of the first heat-generating element 91 is lower than a temperature resistance of the second heat-generating element 92, and a heat dissipation requirement of the second heat-generating element 92 is greater than a heat dissipation requirement of the first heat-generating element 91. Certainly, in other embodiments, the number, the height difference and the arrangement position of the first heat-generating elements 91 and the second heat-generating elements 92 are adjustable according to the practical requirements. The present disclosure is not limited thereto.

In the embodiment, the at least one first liquid cooling chamber 11 and the second liquid cooling chamber 21 are misaligned in the horizontal direction (e.g., on the XY plane) and the vertical direction (i.e., the reverse Z axial direction). Moreover, there is a height difference between the at least one first heat dissipation surface 13 and the second heat dissipation surface 23 in the vertical direction, and the second heat dissipation surface 23 is lower than the at least one first heat dissipation surface 13. In the embodiment, corresponding to the single packaging component 9 with eight higher first heat-generating elements 91 surrounding one lower second heat-generating element 92, the at least one first heat dissipation surface 13 includes eight first heat dissipation surfaces 13 arranged around the second heat dissipation surface 23 in view of the vertical direction, and the second heat dissipation surface 23 is lower than the plurality of first heat dissipation surfaces 13. When the cold plate device 1 is assembled from top to bottom onto the single packaging component 9, the eight first heat dissipation surfaces 13 and the one second heat dissipation surface 23 are attached to the eight first heat-generating elements 91 and the one second heat-generating element 92, respectively, to form a thermal connection. In this way, the first heat dissipation surfaces 13 and the second heat dissipation surface 23 can respectively dissipate heat for different heat-generating elements at different heights and positions while avoiding interference with each other. The design of layered flow channels of the cold plate device 1 is further described below.

In the embodiment, the outer part 101 and the inner part 102 of the main body 10 are engaged with each other to form a square ring-shaped chamber as the first liquid cooling chamber 11, which is misaligned with the protrusion 20 in the vertical direction. The combination of eight first heat dissipation fins 12 and eight first heat dissipation surfaces 13 is detachably disposed at a bottom of the main body 10 through the opening 14 from bottom to top, so that the first heat dissipation fins 12 are accommodated in the first liquid cooling chamber 11 and in fluid communication with each other. In this way, the main body 10 can provide eight first heat dissipation surfaces 13, which are arranged in pairs and disposed adjacent to the four sides of the protrusion 20. Certainly, the present disclosure is not limited thereto. In the embodiment, when the coolant enters the first liquid cooling chamber 11 through the inlet 30, the coolant is split from the left midpoint, for example, and each split flow sequentially passes through four first heat dissipation fins 12 along the horizontal flow direction F1 and then meets at the right midpoint. Thereby, the heat generated from the eight first heat-generating elements 91 thermally connected to the first heat dissipation surfaces 13 is stably removed through the heat exchange between the eight first heat dissipation fins 12 and the coolant. In the embodiment, the impingement flow channel 16 is located at the center of the protrusion 20, and a converging nozzle 161 is used to form an impingement flow for the coolant passing through. In the embodiment, the main body 10 further includes a connection channel 15. The connection channel 15 is in fluid communication with the first liquid cooling chamber 11 and the converging nozzle 161 of the impingement flow channel 16. The coolant flows through the first liquid cooling chamber 11 and then is converged and transported to the converging nozzle 161 of the impingement flow channel 16 from outside to inside in the horizontal direction through the connection channel 15, as shown in FIG. 7.

In the embodiment, the protrusion 20 is protruded downward from the center of the bottom of the main body 10, and the converging nozzle 161 is located at the protrusion 20 and gradually reduces the cross-sectional area in the vertical direction (i.e., the reverse Z axial direction), so that the coolant forms an impingement flow when passing through the converging nozzle 161, and is guided to the center line of the second heat dissipation fin 22 in the second liquid cooling chamber 21 along the vertical flow direction F2 of the impingement flow channel 16, as shown in FIG. 5 and FIG. 6. In the embodiment, the combination of the second heat dissipation fin 22 and the second heat dissipation surface 23 is detachably disposed at the bottom of the protrusion 20 through the opening 240 from bottom to top, so that the second heat dissipation fin 22 is accommodated in the second liquid cooling chamber 21. In this way, the bottom of the protrusion 20 is served as the second heat dissipation surface 23 in a square or rectangular shape. Certainly, the present disclosure is not limited thereto. In the embodiment, after the coolant enters the second liquid cooling chamber 21, the coolant flows through the second heat dissipation fin 22 from the center line of the second heat dissipation fin 22 along the horizontal flow direction F3 to the left and right sides and performs heat exchange, as shown in FIG. 8. Thereby, the heat energy generated by the second heat-generating element 92 thermally connected to the second heat dissipation surface 23 is stably removed through the heat exchange between the second heat dissipation fin 22 and the coolant.

In the embodiment, the cold plate device 1 further includes at least one return flow channel 24, which is vertically embedded in the protrusion 20 and the main body 10 and in fluid communication with the outlet 40. After passing through the second liquid cooling chamber 21, the coolant is further transported upwards through the return flow channels 24, respectively, along the vertical flow direction F4 to the outlet 40 and then discharged, as shown in FIG. 5 and FIG. 6. In the embodiment, the cold plate device 1 further includes an inlet tube 31, an outlet tube 41 and a top cover 17. The inlet 30 and the outlet port 40 are arranged on the top cover 17 and in fluid communication with an exterior through the inlet tube 31 and the outlet tube 41, respectively. The top cover 17 is mounted on the main body 10 from top to bottom to define a recirculation chamber 25. The recirculation chamber 25 is in fluid communication with the outlet 40 and the second liquid cooling chamber 21, and the recirculation chamber 25 and the second liquid cooling chamber 21 are further in fluid communication through at least one return flow channel 24. In the embodiment, the coolant in the second liquid cooling chamber 21 is transferred to the recirculation chamber 25 along the vertical flow direction F4 through at least one return flow channel 24. Then, the coolant is transferred to the outlet 40 along the horizontal flow direction F5 in the recirculation chamber 25 and discharged through the outlet tube 41, as shown in FIG. 6 and FIG. 9.

Notably, in the embodiment, the impingement flow channel 16 is spatially corresponding to a center of the second heat dissipation fin 22, and the at least one return flow channel 24 includes four return flow channels 24 spatially corresponding to four corners of the second heat dissipation fin 22. Preferably but not exclusively, the four return flow channels 24 and the impingement flow channel 16 are misaligned in the vertical direction (i.e., the reverse Z axial direction) and included in a projection range of the second liquid cooling chamber 21 and the second heat dissipation fin 22. In addition, the connection channel 15 and the four return flow channels 24 are misaligned in the vertical direction (i.e., the reverse Z axial direction). Thus, the cold plate device 1 of the present disclosure is designed to connect the first liquid cooling chamber 11, the second liquid cooling chamber 21 and the recirculation chamber 25 in different layers through a specific set of flow channels, so as to achieve the optimal cooling efficiency for omnidirectional heat management, and prevent the heat dissipation path from affecting the operating performance of electronic components at the same time. On the other hand, a central vertical impingement flow channel 16 and a peripheral horizontal flow channel are further formed in the cold plate device 1. It allows the cold plate device to cool and dissipate the heat generated from the central second heat-generating element 92 such as a switch chip and eight surrounding first heat-generating elements 91 such as optical elements. At the same time, it prevents the central high-wattage chip from heating the surrounding optical elements of multiple small-area heat sources and affecting their performance. In other words, different from the conventional liquid cooling plates that handle single-plane heat sources merely, the cold plate device of the present disclosure with omnidirectional heat management is equipped with a multi-level and multi-height adjustable heat dissipation structure to meet multi-dimensional heat dissipation needs. The heat sources at different positions and heights are cooled accurately and individually to maintain the cooling efficiency and uniformity. Certainly, the present disclosure is not limited thereto.

In the embodiment, the cold plate device 1 further includes at least one fastened portion 18 connected to a corner of the main body 10, and configured to fasten the cold plate device 1 on the single package component 9 from top to bottom, so that the at least one first heat dissipation surface 13 is attached to the first heat-generating element 91, and the second heat dissipation surface 23 is attached to the second heat-generating element 92. Certainly, the assembling method of the cold plate device 1 and the single package component 9 is adjustable according to the practical requirements, and the present disclosure is not limited thereto.

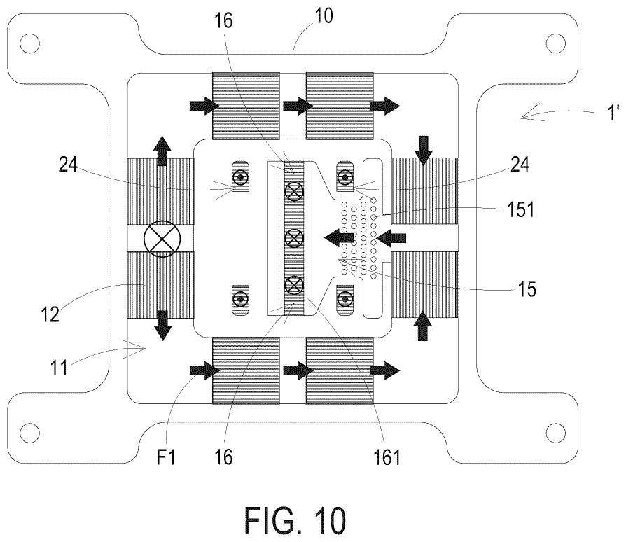

FIG. 10 is a schematic view illustrating a flow direction of a coolant in a first liquid cooling chamber of a cold plate device according to a second embodiment of the present disclosure. In the embodiment, the structures, elements and functions of the cold plate device 1′ are similar to those of the cold plate device 1 of FIG. 1 to FIG. 9, and are not redundantly described herein. In the embodiment, the main body 10 further includes a plurality of spoiler columns 151 spaced apart from each other, disposed in the connection channel 15, and configured to evenly distribute the coolant passing through the connection channel 15. In this configuration, the coolant flowing through the first liquid cooling chamber 11 is evenly distributed by the action of the spoiler columns 151 in the connection channel 15, and then transported to the converging nozzle 161 of the impingement flow channel 16, as shown in FIG. 10. Certainly, the number, the type and the arrangement of spoiler columns 151 are adjustable according to the practical requirements, and the present disclosure is not limited thereto.

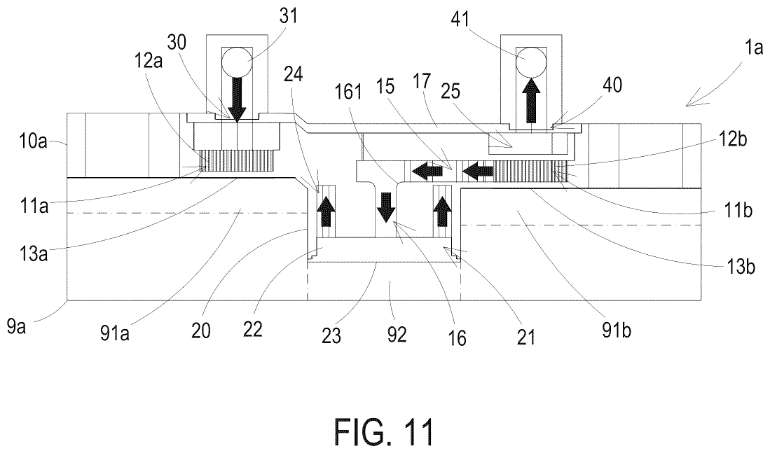

FIG. 11 is a schematic view illustrating a cold plate device combined with heat-generating elements according to a third embodiment of the present disclosure. In the embodiment, the structures, elements and functions of the cold plate device 1a are similar to those of the cold plate device 1 of FIG. 1 to FIG. 9, and are not redundantly described herein. Different from the cold plate device 1 of the aforementioned embodiment including the plurality of first heat dissipation surfaces 13 at the same level, in the embodiment, the main body 10a of the cold plate device 1a includes a first upper liquid cooling chamber 11a, a first lower liquid cooling chamber 11b, a first upper heat dissipation fin 12a, a first lower heat dissipation fin 12b, a first upper heat dissipation surface 13a and a first lower heat dissipation surface 13b. The first upper heat dissipation fin 12a is disposed within the first upper liquid cooling chamber 11a and thermally coupled with the first upper heat dissipation surface 13a. the first lower heat dissipation fin 12b is disposed within the first lower liquid cooling chamber 11b and thermally coupled with the first lower heat dissipation surface 13b. The first upper heat dissipation surface 13a and the first lower heat dissipation surface 13b have different height differences in the vertical direction (i.e., the reverse Z axial direction) relative to the second heat dissipation surface 23. In this way, the first upper heat dissipation surface 13a and the first lower heat dissipation surface 13b are respectively corresponding to the first heat-generating element 91a and the first heat-generating element 91b with different heights in the single package component 9a for heat dissipation. Thereafter, the coolant flowing through the converging nozzle 161 forms the impingement flow, and is guided to the second heat dissipation fin 22 to perform a more efficient heat exchange effect. Certainly, the present disclosure is not limited thereto. In other embodiments, the number, the height difference and the communication order of the first upper heat dissipation surface 13a and the first lower heat dissipation surface 13b are adjustable according to the practical requirements. In other words, the cold plate device 1a with omnidirectional heat management in the present disclosure can dissipate the heat from multiple different heat-generating elements at the same time, and the heat sources of different heat-generating elements may not be limited to the same plane.

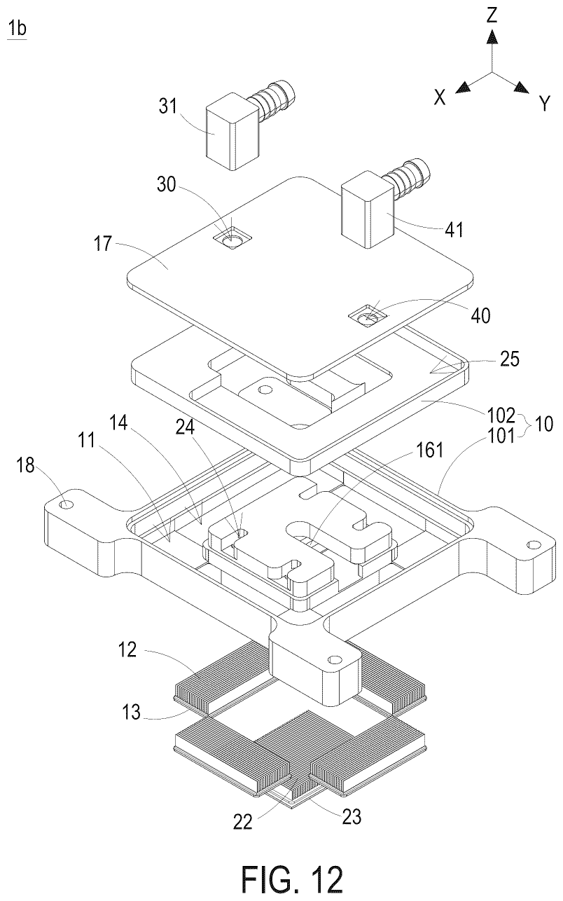

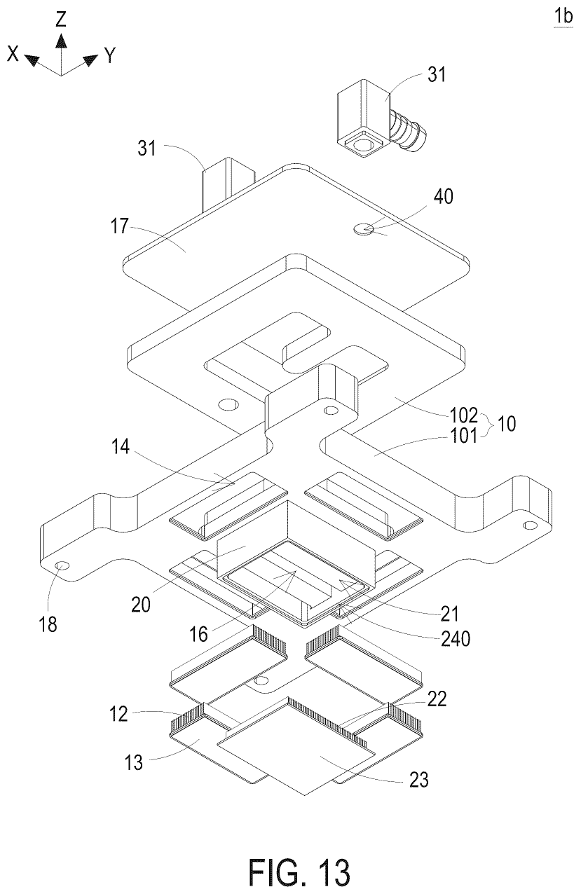

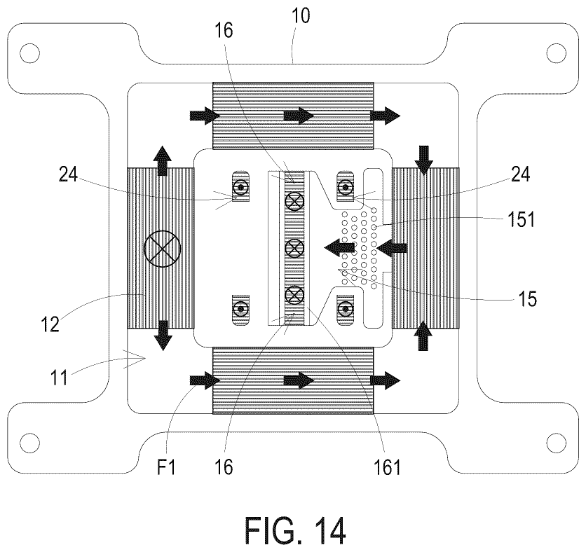

FIG. 12 is a schematic structural view illustrating a cold plate device according to a fourth embodiment of the present disclosure, taken from a top perspective. FIG. 13 is a schematic structural view illustrating the cold plate device according to the fourth embodiment of the present disclosure, taken from a bottom perspective. FIG. 14 is a schematic view illustrating the flow direction of the coolant in the first liquid cooling chamber of the cold plate device according to the fourth embodiment of the present disclosure. In the embodiment, the structures, elements and functions of the cold plate device 1b are similar to those of the cold plate device 1 of FIG. 1 to FIG. 9, and are not redundantly described herein. In the embodiment, the eight sets of the first heat dissipation fins 12 and the first heat dissipation surfaces 13 in the first embodiment are replaced by four sets of the first heat dissipation fins 12 and the first heat dissipation surfaces 13. From bottom to top, the four sets of the first heat dissipation fins 12 and the first heat dissipation surfaces 13 are detachably disposed at the bottom of the main body 10 through the opening 14, so that the first heat dissipation fins 12 are accommodated in the first liquid cooling chambers 11 and in fluid communication with each other. In that, the main body 10 provides four first heat dissipation surfaces 13, which are disposed adjacent to the four sides of the protrusion 20 and have the same heat dissipation effect as that in the first embodiment. On the other hand, due to the structural integration and the number reduction of the first heat dissipation fins 12, the structural strength is strengthened and the assembling process is reduced. Certainly, the ways in which the first heat dissipation fins 12 and the first heat dissipation surfaces 13 are detachably disposed on the main body 10 and the second heat dissipation fin 22 and the second heat dissipation surface 23 are detachably disposed on the protrusion 20 are adjustable according to the practical requirements, and the present disclosure is not limited thereto.

From the above, the heat dissipation fins and the heat dissipation surfaces thermally coupled to each heat-generating element in the cold plate devices 1, 1′, 1a, 1b of the present disclosure can be detachably disposed at the bottom of the main body 10, 10a and the protrusion 20, respectively, and designed in modular. The components can be adjusted and expanded according to the practical requirements to achieve equipment upgrades and changes. For example, the plurality of heat dissipation fins and the plurality of heat dissipation surfaces disposed on the main body can also be designed in several layers with different heights, so as to thermally couple to the corresponding optical elements of different specifications and sizes, thereby achieving diversified configurations and improving the flexibility and adaptability of the overall heat dissipation system. Furthermore, in the embodiment, the heat dissipation fins and the heat dissipation surface are both made of materials with high thermal conductivity coefficients and detachably disposed at the bottoms of the main body 10, 10a and the protrusion 20, respectively. The main body 10, 10a and the protrusion 20 are not limited to being made of the same material, and do not affect the heat dissipation fins and the heat dissipation surfaces to achieve the purposes of improving the structural strength and the heat dissipation efficiency. Certainly, the present disclosure is not limited thereto and not redundantly described hereafter.

In summary, the present disclosure provides a cold plate device with omnidirectional heat management. The cold plate device provides modular heat dissipation fins and heat dissipation surfaces at different positions and heights for multiple heat-generating elements with different temperature resistance and heat dissipation requirements in a single package component, thereby achieving multi-dimensional heat dissipation and ensuring cooling efficiency and uniformity of omnidirectional heat management. For the cold plate device with omnidirectional heat management, the heat sources of multiple different heat-generating elements are cooled at the same time, and the heat sources of different heat-generating elements are not located on the same plane. Although different heat-generating elements packaged in a single component have different temperature resistance and heat dissipation requirements, the cold plate device of the present disclosure utilizes a specific flow channel design to connect the liquid cooling chambers in different layers, so as to achieve the optimal cooling efficiency for omnidirectional heat management, and prevent the heat dissipation path from affecting the operating performance of electronic components at the same time. Taking one single co-packaged optics (CPO) component as an example, the main structure of a CPO component includes a central switch chip, and four pairs of optical elements (optical engines) arranged on the four sides of the switch chip. There are a lot of heat-generating elements. The cold plate device with omnidirectional heat management in the present disclosure forms a central vertical impingement flow channel and a peripheral horizontal flow channel through the design of liquid cooling chambers in different layers of the protrusion and the main body. The central switch chip and the eight surrounding optical elements are cooled effectively. Moreover, it prevents the central high-wattage chip from heating the optical elements located at multiple small-area heat sources around the central high-wattage chip and affecting their performance. In other words, different from the conventional liquid cooling plates that handle single-plane heat sources merely, the cold plate device of the present disclosure with omnidirectional heat management is equipped with a multi-level and multi-height adjustable heat dissipation structure to meet multi-dimensional heat dissipation needs. The heat sources at different positions and heights are cooled accurately and individually to maintain the cooling efficiency and uniformity. The heat dissipation fins and the heat dissipation surfaces thermally coupled to each heat-generating element are allowed to be detachably arranged at the bottoms of the main body and the protrusion, so that a modular design is achieved. The components can be adjusted and expanded according to the practical requirements to achieve equipment upgrades and changes. For example, the multiple heat dissipation fins and multiple heat dissipation surfaces of the main body can also be designed in layers with different heights to correspond to thermal coupling to optical elements of different specifications and sizes. Thereby, diversified configurations are achieved and the flexibility and adaptability of the entire heat dissipation system are improved. Certainly, the present disclosure is not limited thereto.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A cold plate device, comprising:
a main body, comprising at least one first liquid cooling chamber, at least one first heat dissipation fin and at least one first heat dissipation surface, wherein the at least one first heat dissipation fin is disposed within the first liquid cooling chamber, and the at least one first heat dissipation fin is thermally coupled to a first heat-generating element via the at least one first heat dissipation surface;
an inlet, disposed above the main body and in fluid communication with the at least one first liquid cooling chamber, wherein a coolant enters the at least one first liquid cooling chamber through the inlet, and the coolant flows through the at least one first heat dissipation fin along a horizontal direction;
a protrusion, protruded downward from the main body and comprising a second liquid cooling chamber, a second heat dissipation fin and a second heat dissipation surface, wherein the at least one first liquid cooling chamber is in fluid communication with the second liquid cooling chamber via an impingement flow channel, the second heat dissipation fin is disposed within the second liquid cooling chamber, and the second heat dissipation fin is thermally coupled to a second heat-generating element via the second heat dissipation surface, wherein the coolant flows through the impingement flow channel along a vertical direction and is guided to the second heat dissipation fin; and
an outlet, disposed above the main body and in fluid communication with the second liquid cooling chamber, wherein the coolant flows through the second heat dissipation fin, and then is discharged through the outlet.

2. The cold plate device according to claim 1, wherein the at least one first liquid cooling chamber and the second liquid cooling chamber are misaligned in view of the horizontal direction and in view of the vertical direction.

3. The cold plate device according to claim 1, wherein the at least one first heat dissipation surface and the second heat dissipation surface have a height difference in the vertical direction, and the second heat dissipation surface is lower than the at least one first heat dissipation surface.

4. The cold plate device according to claim 1, wherein the at least one first heat dissipation surface includes a plurality of first heat dissipation surfaces arranged around the second heat dissipation surface in view of the vertical direction, and the second heat dissipation surface is lower than the plurality of first heat dissipation surfaces.

5. The cold plate device according to claim 1, wherein the impingement flow channel comprises a converging nozzle, a cross-sectional area of the converging nozzle is gradually decreased along the vertical direction, so that the coolant flowing through the converging nozzle forms an impingement flow and is guided to the second heat dissipation fin.

6. The cold plate device according to claim 1, further comprising an inlet tube, an outlet tube and a top cover, wherein the inlet and the outlet are arranged on the top cover and in fluid communication with an exterior through the inlet tube and the outlet tube, respectively, and the top cover is mounted on the main body from top to bottom to define a recirculation chamber in fluid communication with the outlet and the second liquid cooling chamber.

7. The cold plate device according to claim 6, further comprising at least one return flow channel embedded in the protrusion and the main body, and extended from the recirculation chamber to the second liquid cooling chamber along the vertical direction, wherein the coolant in the second liquid cooling chamber is transported to the recirculation chamber through the at least one return flow channel and then discharged through the outlet.

8. The cold plate device according to claim 7, wherein the at least one return flow channel and the impingement flow channel are misaligned in view of the vertical direction, and included in a projection range of the second liquid cooling chamber.

9. The cold plate device according to claim 8, wherein the impingement flow channel is spatially corresponding to a center of the second heat dissipation fin, and the at least one return flow channel includes four return flow channels spatially corresponding to four corners of the second heat dissipation fin.

10. The cold plate device according to claim 8, wherein the main body further comprises a connection channel, wherein the connection channel is in fluid communication to the at least one first liquid cooling chamber and a converging nozzle of the impingement flow channel, and the connection channel and the at least one return flow channel are misaligned in view of the vertical direction.

11. The cold plate device according to claim 10, wherein the main body further comprises a plurality of spoiler columns, which are spaced apart from each other, disposed in the connection channel, and configured to evenly distribute the coolant passing through the connection channel.

12. The cold plate device according to claim 1, wherein the at least one first heat dissipation fin and the at least one first heat dissipation surface are detachably arranged at a bottom of the main body, wherein the second heat dissipation fin and the second heat dissipation surface are detachably arranged at a bottom of the protrusion.

13. The cold plate device according to claim 1, wherein the at least one first liquid cooling chamber comprises a first upper liquid cooling chamber and a first lower liquid cooling chamber, the at least one first heat dissipation fin comprises a first upper heat dissipation fin and a first lower heat dissipation fin, and the at least one first heat dissipation surface comprises a first upper heat dissipation surface and a first lower heat dissipation surface, wherein the first upper heat dissipation fin is disposed within the first upper liquid cooling chamber and thermally coupled with the first upper heat dissipation surface, and the first lower heat dissipation fin is disposed within the first lower liquid cooling chamber and thermally coupled with the first lower heat dissipation surface, wherein the first upper heat dissipation surface and the first lower heat dissipation surface have different height differences relative to the second heat dissipation surface in the vertical direction.

14. The cold plate device according to claim 1, wherein the protrusion protrudes downward from a center of a bottom of the main body, the second heat dissipation surface is square or rectangular and located on a bottom of the protrusion, and the at least one first heat dissipation surface comprises eight first heat dissipation surfaces, which are arranged in pairs on four sides of the protrusion.

15. The cold plate device according to claim 1, wherein a temperature resistance of the first heat-generating element is lower than a temperature resistance of the second heat-generating element, and a heat dissipation requirement of the second heat-generating element is greater than a heat dissipation requirement of the first heat-generating element, wherein the first heat-generating element is an optical element, and the second heat-generating element is a chip.

16. The cold plate device according to claim 1, wherein the first heat-generating element and the second heat-generating element are packaged in a single co-packaged optics (CPO) component, the first heat-generating element comprises a photonic integrated circuit (PIC), and the second heat-generating element comprises an electronic integrated circuit (EIC).

17. The cold plate device according to claim 1, further comprising at least one fastened portion connected to a corner of the main body, and configured to fasten the cold plate device, so that the at least one first heat dissipation surface is attached to the first heat-generating element and the second heat dissipation surface is attached to the second heat-generating element.
